(19) United States
(12) Patent Application Publication
(10) Pub. No.: US 2025/0309049 A1
(43) Pub. Date: Oct. 2, 2025

(54) INTEGRATED COOLING ASSEMBLIES WITH MULTIFUNCTIONAL LAYERS AND METHODS OF MANUFACTURING THE SAME

(71) Applicant: Adeia Semiconductor Bonding Technologies Inc., San Jose, CA (US)

(72) Inventors: Gaius Gillman Fountain, JR., Youngsville, NC (US); Pawel Mrozek, San Jose, CA (US); George Carlton Hudson, Wendell, NC (US)

(21) Appl. No.: 18/674,651

(22) Filed: May 24, 2024

Related U.S. Application Data
(60) Provisional application No. 63/571,896, filed on Mar. 29, 2024.

(51) Int. Cl. H01L 23/473; H01L 23/00; H01L 23/055; H01L 23/08; H01L 23/14; H01L 23/498; H01L 25/065

(52) U.S. Cl. CPC H01L 23/473; H01L 23/055; H01L 23/08; H01L 23/14; H01L 23/49811; H01L 25/0652; H01L 24/16; H01L 2224/16225

(57) ABSTRACT

Embodiments herein provide for integrated cooling assemblies embedded within a device package and related manufacturing methods. In one embodiment, an integrated cooling assembly comprises a semiconductor device and a cold plate attached to the semiconductor device by direct bonds with a multifunctional layer disposed therebetween. The cold plate comprises a perimeter sidewall, a top portion, and a cavity divider comprising cavity sidewalls. The perimeter sidewall extends downwardly from the top portion to a backside of the semiconductor device to define a perimeter of the cold plate. The cavity divider extends downwardly from the top portion towards the backside of the semiconductor device. The cavity sidewalls, the perimeter sidewall and the backside of the semiconductor device collectively define coolant channels therebetween. The multifunctional layer comprises a nitride.

### CROSS-REFERENCE TO RELATED APPLICATION

This application claims the benefit of U.S. Provisional Patent Application No. 63/571,896, filed Mar. 29, 2024, which is incorporated by reference in its entirety.

### FIELD

The present disclosure relates to advanced packaging for microelectronic devices, and in particular, cooling systems for device packages and methods of manufacturing the same.

### BACKGROUND

Energy consumption poses a critical challenge for the future of large-scale computing as the world's computing energy requirements are rising at a rate that most would consider unsustainable. Some models predict that the information, communication and technology (ICT) ecosystem could exceed 20% of global electricity use by 2030, with direct electrical consumption by large-scale computing centers accounting for more than one-third of that energy usage. A significant portion of the energy used by such large-scale computing centers is devoted to cooling since even small increases in operating temperatures can negatively impact the performance of microprocessors, memory devices, and other electronic components. While some of this energy is expended to operate the cooling systems that are directly cooling the chips (e.g. heat spreaders, heat pipes, etc.), energy consumption/costs for indirect cooling can also be quite staggering. Indirect cooling energy costs include, for example, cooling or air conditioning of data center buildings. Data center buildings can house thousands, to tens of thousands or more, of high performance chips in server racks and each of those high performance chips is a heat source. An uncontrolled ambient temperature in a data center will adversely affect the performance of the individual chips and the data center system performance as a whole.

Thermal dissipation in high-power density chips (semiconductor devices/die) is also a critical challenge as improvements in chip performance, e.g., through increased gate or transistor density due to advanced processing nodes, evolution of multi-core microprocessors, etc. have resulted in increased power density and a corresponding increase in thermal flux that contributes to elevated chip temperatures. Higher density of transistors also increases the length of metal wiring on the chips, which generates its own additional thermal flux due to Joule heating of these wires due to higher currents. These elevated temperatures are undesirable as they can degrade the chip's operating performance, efficiency, reliability, and remaining life. Cooling systems used to maintain the chip at a desired operating temperature typically remove heat using one or more heat dissipation devices, e.g., thermal spreaders, heat pipes, cold plates, liquid cooled heat pipe systems, thermal-electric coolers, heat sinks, etc. One or more thermal interface material(s), such as, for example, thermal paste, thermal adhesive, or thermal gap filler, may be used to facilitate heat transfer between the surfaces of a chip and heat dissipation device(s). A thermal interface material(s) (TIM(s)) is any material that is inserted between two components to enhance the thermal coupling therebetween. Unfortunately, the combined thermal resistance of (i) the thermal resistance of interfacial boundary regions between a TIM(s) and the chip and/or the heat dissipation device(s); and (ii) the thermal resistance of a thermal interface material(s) itself can inhibit heat transfer from the chip to the heat dissipation devices, undesirably reducing the cooling efficiency of the cooling system.

Generally speaking, there are multiple components between the heat dissipating sources (i.e., active circuitry) in the chips and the heat dissipation devices, each of which contribute to the system thermal resistance accumulatively along the heat transfer paths and raise chip junction temperatures from the ambient. Additional material layers disposed between the heat dissipation sources and the heat dissipation devices may further contribute to the system thermal resistance. In particular, where multiple layers of materials are disposed between the heat dissipation sources and the heat dissipation devices, a resulting thickness of the multiple material layers may be undesirable for optimum cooling.

Such cooling systems can suffer from reduced cooling efficiency due to the design and manufacture of system components.

Accordingly, there exists a need in the art for improved energy-efficient cooling systems, by reducing system thermal resistance, and methods of manufacturing the same.

### SUMMARY

Embodiments herein provide integrated device cooling assemblies embedded in advanced device packages. Advantageously, the integrated device cooling assemblies provide improved cooling efficiency by using a relatively thin layer of multifunctional material.

A first general aspect includes an integrated cooling assembly comprising a semiconductor device and a cold plate attached to the semiconductor device with a multifunctional layer disposed therebetween. The cold plate comprises a perimeter sidewall, a top portion, and a cavity divider comprising cavity sidewalls. The perimeter sidewall extends downwardly from the top portion to a backside of the semiconductor device to define a perimeter of the cold plate. The cavity divider extends downwardly from the top portion towards the backside of the semiconductor device. The cavity sidewalls, the perimeter sidewall and the backside of the semiconductor device collectively define coolant channels therebetween. The multifunctional layer comprises a nitride (e.g., silicon nitride or silicon carbon nitride).

Implementations of the integrated cooling assembly may include one of more of the following. A thickness of the multifunctional layer in a direction orthogonal to the backside of the semiconductor device may be less than or equal to 1 micrometer (μm).

Implementations of the integrated cooling assembly may include one of more of the following. A thickness of the multifunctional layer in a direction orthogonal to the backside of the semiconductor device may be less than or equal to 50 nanometers (nm).

Implementations of the integrated cooling assembly may include one of more of the following. A thickness of the multifunctional layer in a direction orthogonal to the backside of the semiconductor device may be 20 nm to 1 μm.

Implementations of the integrated cooling assembly may include one of more of the following. A thickness of the multifunctional layer in a direction orthogonal to the backside of the semiconductor device may be 20 nm to 50 nm.

Implementations of the integrated cooling assembly may include one of more of the following. The cold plate may be attached to the semiconductor device using direct dielectric bonds formed between the multifunctional layer and the cold plate.

Implementations of the integrated cooling assembly may include one of more of the following. The cold plate may be attached to the semiconductor device using direct hybrid bonds formed between the multifunctional layer and the cold plate.

A second general aspect includes a package device comprising the integrated cooling assembly of the first general aspect. The package device includes a package substrate. The integrated cooling assembly is attached to the package substrate.

A third general aspect includes a semiconductor device comprising an active side and a backside opposite the active side. The backside comprises a multifunctional layer. The multifunctional layer comprises a nitride (e.g., an SiₓO_{y}N_{z}, an insulating nitride, a silicon nitride, an oxynitride, a silicon oxynitride, or a silicon carbon nitride, etc.).

A fourth general aspect includes a method of manufacturing the integrated cooling assembly of the first general aspect. The method includes directly bonding a first substrate comprising the cold plate to a second substrate comprising the semiconductor device using the multifunctional layer. The multifunctional layer comprises a nitride (e.g., an SiₓO_{y}N_{z}, an insulating nitride, a silicon nitride, an oxynitride, a silicon oxynitride, or a silicon carbon nitride, etc.). The method further includes singulating the integrated cooling assembly comprising the semiconductor device and the cold plate from the bonded first and second substrates.

A fifth general aspect includes a method of manufacturing the package device of the second general aspect. The method includes connecting the integrated cooling assembly of the first general aspect to the package substrate. The method further comprises sealing the package cover comprising the inlet and outlet openings to the integrated cooling assembly.

### BRIEF DESCRIPTION OF THE DRAWINGS

The above and other objects and advantages of the disclosure will be apparent upon consideration of the following detailed description, taken in conjunction with the accompanying drawings, in which:

FIG. 1 illustrates a device package with an external heat sink;

FIG. 2A is a schematic plan view of an example of a system panel, in accordance with embodiments of the disclosure;

FIG. 2B is a schematic partial sectional side view of a device package mounted on a PCB, in accordance with embodiments of the disclosure;

FIG. 2C is a schematic exploded isometric view of the device package in FIG. 2B.

FIG. 3 is a schematic sectional view of an example device package, in accordance with embodiments of the present disclosure, that may be used with the system panel;

FIG. 4 is a schematic sectional view of an integrated cooling assembly of the device package, according to some embodiments;

FIG. 5 is a schematic sectional view of another example device package, in accordance with embodiments of the present disclosure, that may be used with the system panel;

FIG. 6 shows a method that can be used to manufacture the device package described herein;

FIG. 7 is an isometric view of a cold plate in accordance with one or more embodiments;

FIG. 8 is a schematic sectional view of another integrated cooling assembly of the device package, according to some embodiments;

FIG. 9 is a schematic sectional view of another integrated cooling assembly of the device package, according to some embodiments;

FIG. 10 is a schematic sectional view of another integrated cooling assembly of the device package, according to some embodiments; and

FIG. 11 is a schematic sectional view of another integrated cooling assembly of the device package, according to some embodiments.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

As used herein, the term “substrate” means and includes any workpiece, wafer, or article that provides a base material or supporting surface from which or upon which components, elements, devices, assemblies, modules, systems, or features of the heat-generating devices, packaging components, and cooling assembly components described herein may be formed or mounted. The term substrate also includes “semiconductor substrates” that provide a supporting material upon which elements of a semiconductor device are fabricated or attached, and any material layers, features, and/or electronic devices formed thereon, therein, or therethrough. Examples of substrate material that may be used in applications that generate high thermal density include, but are not limited to, Si, GaN, SiC, InP, GaP, InGaN, AlGaInP, AlGaAs, etc.

As described below, the semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active sides” and “non-active sides” are also used to describe surfaces of material layers or features formed on, in, or through the semiconductor substrate, whether or not the material layers or features are ultimately present in the fabricated or assembled device. For example, in some instances, the term “active side” is used to indicate a surface of a substrate that will in the future, but does not yet, include semiconductor device elements.

Spatially relative terms are used herein to describe the relationships between elements, such as the relationships between substrates, heat-generating devices, cooling assembly components, device packaging components, and other features described below. Unless the relationship is otherwise defined, terms such as “above,” “over,” “upper,” “upwardly,” “outwardly,” “on,” “below,” “under,” “beneath,” “lower,” “top,” “bottom” and the like are generally made with reference to the X, Y, and Z directions set forth by X, Y and Z axis in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements. Furthermore, the term “horizontal” is generally made with reference to the X-axis direction and the Y-axis direction set forth in the drawings. The term “vertical” is generally made with reference to the Z-axis direction set forth in the drawings.

Various embodiments disclosed herein include bonded structures in which two or more elements are directly bonded to one another without an intervening adhesive (referred to herein as “direct bonding”, or “directly bonded”). In some embodiments, direct bonding includes the bonding of a single material on the first of the two or more elements and a single material on a second one of the two or more elements, where the single material on the different elements may or may not be the same. For example, bonding a layer of one inorganic dielectric (e.g. silicon oxide) to another layer of the same or different inorganic dielectric. As discussed in more detail below, the process of direct bonding provides a reduction of thermal resistance between a semiconductor device and a cold plate. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (1^{st}) nonconductive feature directly bonded to another (2^{nd}) nonconductive feature, and ii) at least one (1^{st}) conductive feature directly bonded to another (2^{nd}) conductive feature, without any intervening adhesive. In some hybrid bonding embodiments, there are many 1^{st} conductive features, each directly bonded to a 2^{nd} conductive feature, without any intervening adhesive. In some embodiments, nonconductive features on the first element are directly bond to nonconductive features of the second element at room temperature without any intervening adhesive, which is followed by bonding of conductive features of the first element directly bonded to conductive features of the second element at via annealing at slightly higher temperatures (e.g. >100° C., >200° C., >250° C., >300° C., etc.)

Unless otherwise noted, the terms “cooling assembly” and “integrated cooling assembly” generally refer to a semiconductor device and a cold plate attached to the semiconductor device. Typically, the cold plate is formed with recessed surfaces that define one or more fluid cavities (e.g., coolant chamber volume(s) or coolant channel(s)) between the cold plate and the semiconductor device. In embodiments where the cold plate is formed with plural fluid cavities, each fluid cavity may be defined by cavity dividers and/or sidewalls of the cold plate. For example, cavity dividers may be spaced apart from each other and extend laterally between opposing cold plate sidewalls (e.g., in one direction between a first pair of opposing cold plate sidewalls, or in two directions between orthogonal pairs of opposing cold plate sidewalls). The cavity dividers and the cold plate sidewalls may collectively define adjacent fluid cavities therebetween. The cold plate may comprise a polymer material. The cold plate may be attached to the semiconductor device by use of a compliant adhesive layer or by direct bonding or hybrid bonding. For example, the cold plate may include material layers and/or metal features which facilitate direct bonding or hybrid bonding with the semiconductor device. Beneficially, the backside of the semiconductor device is directly exposed to coolant fluids flowing through the integrated cooling assembly, thus providing for direct heat transfer therebetween. Unless otherwise noted, the integrated cooling assemblies described herein may be used with any desired fluid, e.g., liquid, gas, and/or vapor-phase coolants, such as water, glycol etc. In some embodiments, the coolant fluid(s) may contain additives to enhance the conductivity of the coolant fluid(s) within the integrated cooling assemblies. The additives may comprise, for example, nano-particles of carbon nanotubes, nano-particles of graphene, and/or nano-particles of metal oxides. The concentration of these nano-particles may be less than 1%, less than 0.2%, or less than 0.05%. The coolant fluids may also contain small amount of glycol or glycols (e.g. propylene glycol, ethylene glycol, etc.) to reduce frictional shear stress and drag coefficient in the coolant fluid(s) within the integrated cooling assembly.

This disclosure describes embodiments involving the architecture of system and component elements that can be employed to provide for the cooling of semi-conductor components, packaging, and boards. However, those skilled in the art will appreciate the disclosed components and arrangements can be deployed and used in scenarios where component heat up or thermal warm up is desired for a component that is currently outside the low end of the desired operational range. Components that are outside the low end of their operational range can, if started in a cold environment, experience thermal warping or cracking up to and including thermal overexpansion and contact separation that may impair the successful operation of the system. Therefore, in these scenarios, the architectures and embodiments disclosed herein can be used where the indirect thermal solutions supporting them are repurposed or operated in a hybrid configuration to provide warming fluids or heat transfer media to accomplish the warm-up or heat-up scenario. These scenarios are controlled by systems not shown here to bring temperatures up at a speed or timing that enables the materials to avoid the excessive thermal expansion or unequal thermal expansion that may occur among the materials of the semiconductor or packaging being serviced by the thermal solution. Once the component or packaging is brought up into the normal operating range, it can be safely started and brought to a useful operational state.

Considering the warm-up or heat-up embodiments introduced above, the balance of this disclosure and terms used should be viewed in a light that also considers the design option for such warm-up or heat-up. Thus, where terms such as cooling channel, cooling chamber volume, and cooling port are used, for example, such terms could also be considered as a thermal control channel, a thermal control volume, or a thermal control port, respectively. A person of skill would understand that heat flux or heat transfer would go in a different direction, but the design concepts are similar and can be successfully employed in the various embodiments.

In some embodiments, a coolant channel is a liquid coolant channel and a liquid may flow through the liquid coolant channel. In some embodiments, the liquid may comprise a water and/or glycol (e.g. propylene glycol, ethylene glycol, and mixtures thereof).

As described below, coolant fluid flowing through a cold plate may be used to control the temperature of semiconductor devices. The fluid flowing across the surface of the semiconductor device absorbs heat and conducts heat away from the semiconductor device.

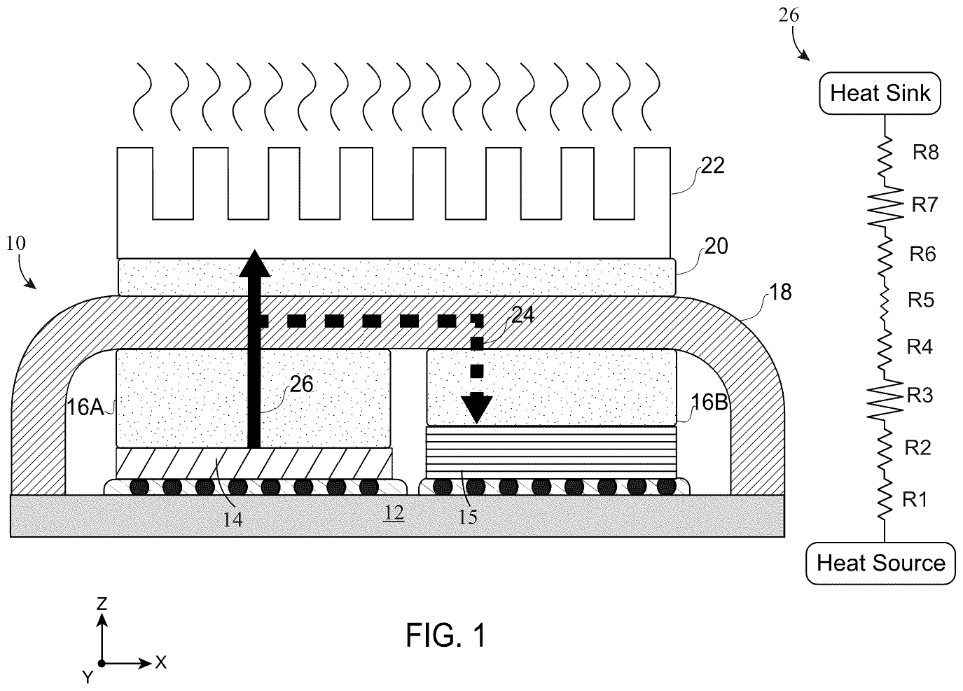

FIG. 1 is a schematic side view of a device package 10 and a heat sink 22 attached to the device package 10. The device package 10 typically includes a package substrate 12, a first device 14, a device stack 15, a heat spreader 18, and first TIM layers 16A, 16B thermally coupling the first device 14 and device stack 15 to the heat spreader 18. The device package 10 is thermally coupled to a heat sink 22 through a second TIM layer 20. The TIM layers 16A, 16B, 20 facilitate thermal contact between components in the device package 10 and between the device package 10 and the heat sink 22.

Unfortunately, as heat flux density increases with increasing power density in advanced semiconductor devices, the cumulative thermal resistance of the system illustrated in FIG. 1 is increasingly problematic as heat cannot be dissipated quickly enough to allow semiconductor devices to run at optimal power. Consequently, the energy efficiency of semiconductor devices is reduced. Furthermore, heat is transferred between semiconductor devices within the device package 10, as shown with heat transfer path 24 (illustrated as a dashed line), where heat may be undesirable transferred from the first device 14 having a high heat flux, such as a CPU or GPU, to the device stack 15 having low heat flux, such as memory, through the heat spreader 18.

For example, as shown in FIG. 1, each device package component and the respective interfacial boundaries therebetween has a corresponding thermal resistance which forms heat transfer path 26 (illustrated by arrow 26 in FIG. 1). The left-hand side of FIG. 1 illustrates the heat transfer path 26 as a series of thermal resistances R1-R8 between a heat source and a heat sink. Here, R1 is the thermal resistance of the bulk semiconductor material of the first device 14. R3 and R7 are the thermal resistances of the first TIM layers 16A, 16B and the second TIM layer 20, respectively. R5 is the thermal resistance of the heat spreader 18. R2, R4, R6, and R8 represent the thermal resistance at the interfacial region of the components (e.g., contact resistances). In a typical cooling system, R3 and R7 may account for 80% or more of the cumulative thermal resistance of the heat transfer path 26 and R5 may account for 5% or more. R1 of the first device 14 and R2, R4, R6, and R8 of the interfaces account for the remaining cumulative thermal resistance. Accordingly, embodiments herein provide for integrated cooling assemblies embedded within a device package. The embedded cooling assemblies shorten the thermal resistance path between a semiconductor device and a heat sink and reduce thermal communication between semiconductor devices disposed in the same device package, such as described in relation to the figures below.

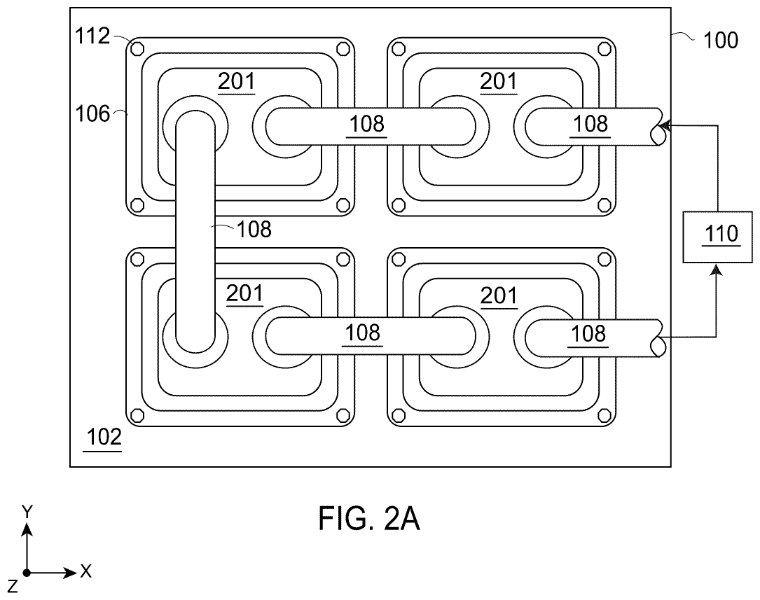

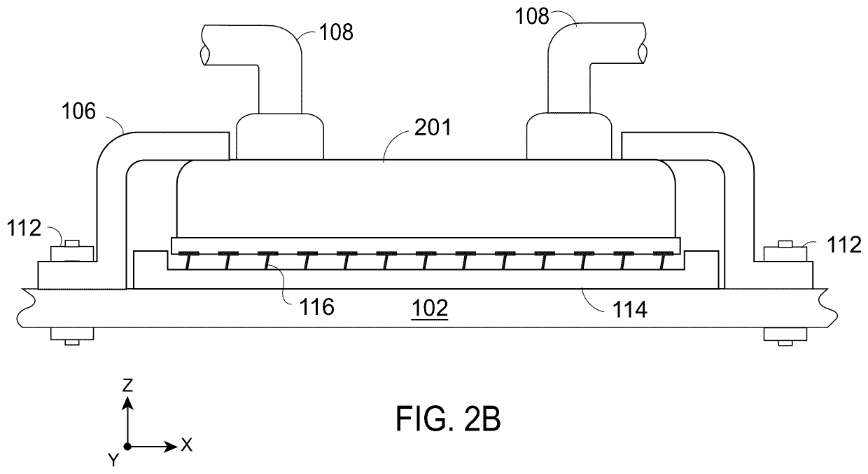

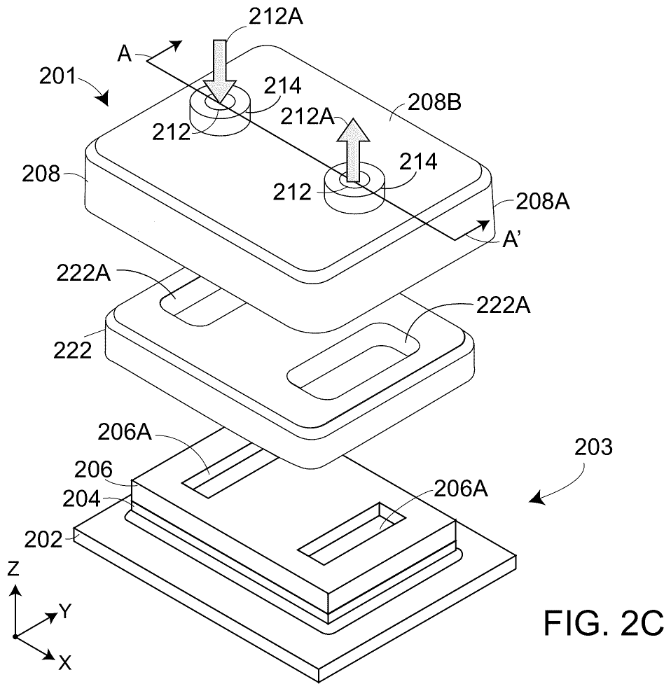

FIG. 2A is a schematic plan view of an example of a system panel 100, in accordance with embodiments of the disclosure. Generally, the system panel 100 includes a printed circuit board, here PCB 102, a plurality of device packages 201 mounted to the PCB 102, and a plurality of coolant lines 108 fluidly coupling each of the device packages 201 to a coolant source 110. It is contemplated that coolant fluid may be delivered to each of the device packages 201 in any desired fluid phase, e.g., liquid, vapor, gas, or combinations thereof and may flow out from each device package 201 in the same phase or a different phase. In some embodiments, the coolant fluid is delivered to the device packages 201 and returned therefrom as a liquid, whereby the coolant source 110 may comprise a heat exchanger or chiller to maintain the coolant fluid at a desired temperature. In other embodiments, the coolant fluid may be delivered to the device packages 201 as a liquid, vaporized to a vapor within the device packages 201, and returned to the coolant source 110 as a vapor. In those embodiments, the device packages 201 may be fluidly coupled to the coolant source 110 in parallel and the coolant source 110 may include or further include a compressor (not shown) for condensing the received vapor to a liquid form.

FIG. 2B is a schematic partial sectional side view of a portion of the system panel 100 of FIG. 2A. As shown, each device package 201 is fluidly coupled to the plurality of coolant lines 108 and is disposed in a socket 114 of the PCB 102 and connected thereto using a plurality of pins 116, or by other suitable connection methods, such as solder bumps (not shown). The device package 201 may be seated in the socket 114 and secured to the PCB 102 using a mounting frame 106 and a plurality of fasteners 112, e.g., compression screws, collectively configured to exert a relatively uniform downward force on the upward facing edges of the device package 201. The uniform downward force ensures proper pin contact between the device package 201 and the socket 114.

FIG. 2C is a schematic exploded isometric view of an example device package 201, in accordance with embodiments of the disclosure. Generally, the device package 201 includes a package substrate 202, an integrated cooling assembly 203 disposed on the package substrate 202, and a package cover 208 disposed on a peripheral portion of the package substrate 202. Suitable materials that may be used in the package cover 208 include copper, aluminum, metal alloys, etc. The package cover 208 extends over the integrated cooling assembly 203 so that the integrated cooling assembly 203 is disposed between the package substrate 202 and the package cover 208. The integrated cooling assembly 203 typically includes a semiconductor device 204 and a cold plate 206 bonded to the semiconductor device 204. In some embodiments, the cold plate 206 may comprise substrate material like silicon, glass, ceramic, etc. Although the lateral dimensions (or footprint) of the cold plate 206 is shown to be the same or similar to the lateral dimensions (or footprint) of the semiconductor device 204, the footprint of the cold plate 206 may be smaller or larger in one or both directions when compared to the footprint of the semiconductor device 204.

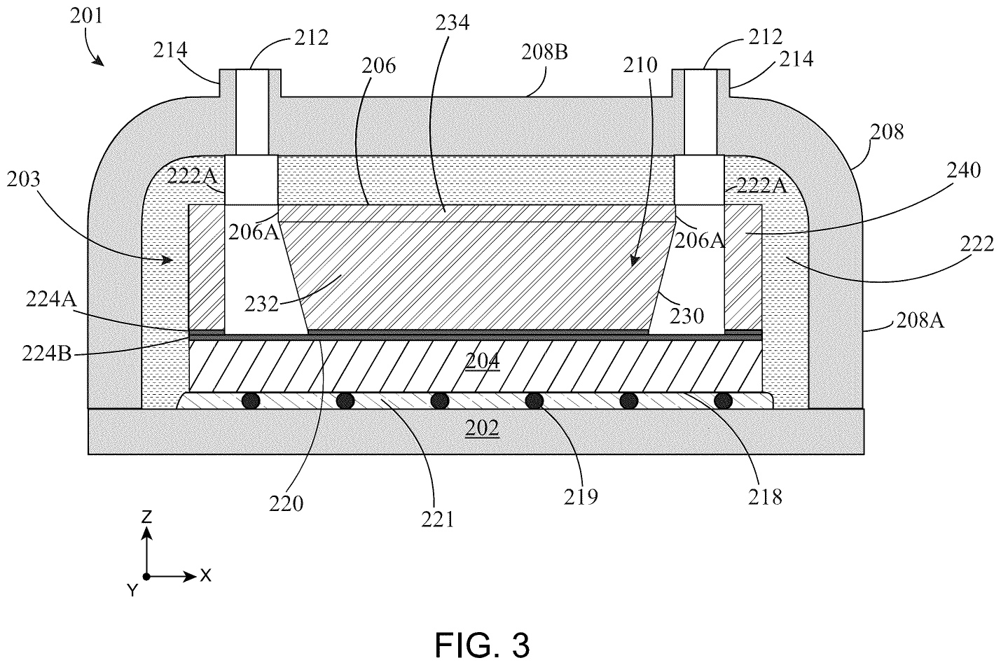

As shown, the device package 201 further includes a sealing material layer 222 that forms a coolant fluid impermeable barrier between the package cover 208 to the integrated cooling assembly 203 that prevents the leaking of the coolant fluid outside of the cooling assembly and prevents coolant fluid from reaching an active side 218 (discussed below in relation to FIG. 3) of the semiconductor device 204 and causing damage thereto. In some embodiments, the sealing material layer 222 comprises an adhesive material that reliably attaches the package cover 208 to the integrated cooling assembly 203. In some embodiments, the sealing material layer 222 comprises a polymer or epoxy material that extends upwardly from the package substrate 202 to encapsulate and/or surround at least a portion of the semiconductor device 204. In some embodiments, the sealing material layer 222 may also comprise conductive material, e.g. solder. In some embodiments, the sealing material layer 222 is formed from a molding compound, e.g., a thermoset resin, that when polymerized, forms a hermetic seal between the package cover 208 and the cold plate 206. Here, coolant fluid is delivered to the cold plate 206 through openings 222A disposed through the sealing material layer 222. As shown, the openings 222A are respectively in registration and fluid communication with inlet and outlet openings 212 of the package cover 208 thereabove and inlet and outlet openings 206A in the cold plate 206 therebelow. It will be understood that the openings are shown in a section view. The openings may have any cross-sectional shape that allows fluid to flow therethrough (e.g., rectangular, square, hexagonal or circular cross-sections). For example, the inlet and outlet openings 206A of the cold plate 206 may form an elongated shape extending from one side of the cold plate 206 to another side of the cold plate 206. For example, the inlet and outlet openings 206A may form any shape having a length greater than a width in the X-Y plane (e.g., a rectangular or a trapezoidal shape). A shape in the X-Y plane of the openings 222A disposed through the sealing material layer 222 may be substantially the same as the shape of the inlet and outlet openings 206A of the cold plate 206 in the same place. Furthermore, it will be understood that all references to an opening throughout the present disclosure refer to an opening defined by a sidewall (e.g., opening sidewall).

Generally, the package substrate 202 includes a rigid material, such as an epoxy or resin-based laminate, that supports the integrated cooling assembly 203 and the package cover 208. The package substrate 202 may include conductive features disposed in or on the rigid material that electrically couple the integrated cooling assembly 203 to a system panel, such as the PCB 102.

FIG. 3 is a schematic sectional view in the X-Z plane of the device package 201 taken along line A-A′ of FIG. 2C. As illustrated in FIG. 3, the semiconductor device 204 includes the active side 218 that includes device components, e.g., transistors, resistors, and capacitors, formed thereon or therein, and a non-active side, here the semiconductor device backside 220, opposite the active side 218. As shown, the active side 218 is positioned adjacent to and facing towards the package substrate 202. The active side 218 may be electrically connected to the package substrate 202 by use of conductive bumps 219, which are encapsulated by a first underfill layer 221 disposed between the semiconductor device 204 and the package substrate 202. The first underfill layer 221 may comprise a cured polymer resin or epoxy, which provides mechanical support to the conductive bumps 219 and protects against thermal fatigue. In some embodiments, the active side 218 may be electrically connected to another package substrate, another active die, or another passive die (e.g. interposer) using hybrid bonding or conductive bumps 219. The cold plate 206 may be disposed above the package substrate 202 with the semiconductor device 204 disposed therebetween. For example, the semiconductor device 204 (and the first underfill layer 221) may be disposed between the cold plate 206 and the package substrate 202. In some embodiments, the cold plate 206 may be disposed directly on the package substrate 202.

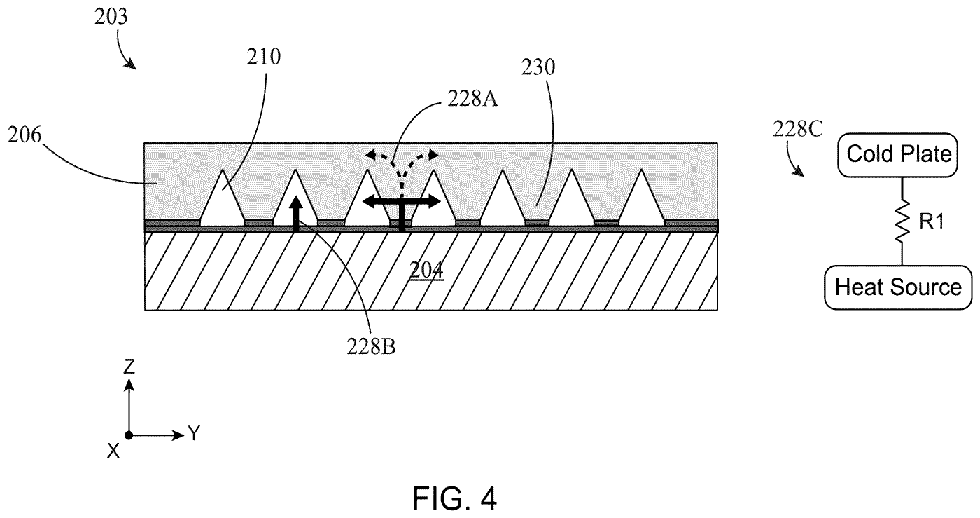

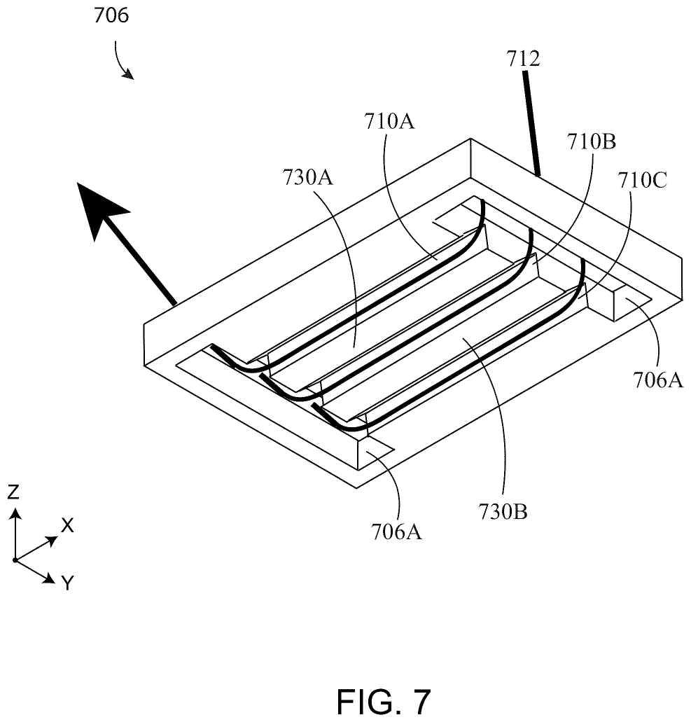

Here, the cold plate 206 comprises a top portion 234 and a sidewall 240 (e.g., a perimeter sidewall defining a perimeter of the cold plate 206) extending downwardly from the top portion 234 to the backside 220 of the semiconductor device 204. The top portion 234, the perimeter sidewall 240, and the backside 220 of the semiconductor device 204 collectively define a coolant channel 210 therebetween. The cold plate 206 comprises cavity dividers 230 extending downwardly from the top portion 234 towards the backside 220 of the semiconductor device 204. The cavity dividers 230 may extends laterally and in parallel between an inlet opening 206A of the cold plate 206 and an outlet opening 206B of the cold plate 206 to define coolant channels 210 therebetween. It should be appreciated that, the cold plate 206 may comprise one cavity divider 230 which forms two coolant channels (e.g., one coolant channel on either side of the cavity divider 230) by means of the cavity divider 230 and portions of the perimeter sidewall 240. More specifically, coolant channels 210 may be formed between the cavity divider 230 and a portion of the perimeter sidewall 240 extending parallel to the cavity divider 230. Alternatively, in other embodiments, the cold plate 206 may comprise plural cavity dividers 230, for example two cavity dividers (as illustrated in FIG. 7), five cavity dividers, or six cavity dividers (as illustrated in FIG. 4). In such examples, the cold plate 206 comprises more than two coolant channels 210, for example three coolant channels, four coolant channels, seven coolant channels, or more, defined between the cavity dividers 230 and/or the cavity divider(s) 230 and the perimeter sidewall 240.

The cavity dividers 230 comprise cavity sidewalls 232 which form surfaces of corresponding coolant channels 210. In embodiments where plural cavity dividers 230 extend in parallel to each other, cavity sidewalls 232 of adjacent cavity dividers 230 are opposite (e.g., facing) each other. In embodiments comprising a single cavity divider 230, a first cavity sidewall may be opposite (e.g., face) a first portion of the perimeter sidewall 240 extending parallel to and facing the first cavity sidewall. A second cavity sidewall may be opposite (e.g., face) a second portion of the perimeter sidewall 240 extending parallel to and facing the second cavity sidewall. The first portion of the perimeter sidewall 240 may be an opposite side of the cold plate 206 to the second portion of the perimeter sidewall 240. For example, in embodiments where the cold plate 206 is rectangular, first and second opposing sides of the rectangular cold plate 206 form the first and second portions of the perimeter sidewall 240.

The cavity dividers 230 may be continuous cavity dividers which extend continuously (e.g., in the Y-axis direction) between the inlet opening 206A and the outlet opening 206B of the cold plate 206.

With reference to FIG. 3, coolant channels 210 may be defined by:
the backside 220 of the semiconductor device 204, which forms lower coolant channel surfaces;
portions of the perimeter sidewall 240 extending in the Y-axis direction, which form end surfaces of the coolant channels 210;
the cavity sidewalls 232, which form inner surfaces of the coolant channels 210 in the X-axis direction; and
portions of the perimeter sidewall 240 extending in the X-axis direction, which form outer surfaces of the coolant channels 210 in the X-axis direction.

Here, the cavity sidewalls 232 are formed at an acute angle with respect to the backside 220 of the semiconductor device 204 such that upper portions of opposing (e.g., facing) cavity sidewalls 232 meet. Therefore, the cavity sidewalls 232 and the backside 220 of the semiconductor device 204 collectively define a triangular cross-section of the coolant channel 210.

In some embodiments, the backside 220 of the semiconductor device 204 comprises a corrosion protective layer (not shown). The corrosion protective layer may be a continuous layer disposed across the entire backside 220 of the semiconductor device 204, such that the cold plate 206 is attached thereto. Beneficially, the corrosion protective layer provides a corrosion resistant barrier layer, thus preventing undesired corrosion of the semiconductor device 204 (e.g., the semiconductor substrate material which might otherwise be in direct contact with coolant fluid flowing through a coolant chamber volume).

The coolant chamber volume may include one or more coolant channels. The coolant channels may extend between a single inlet opening and a single outlet opening of the cold plate 206, such that the coolant channels share the same inlet and outlet openings. In some embodiments, multiple inlet and/or outlet openings may be coupled to the coolant channels.

Each coolant channel may be connected between a separate inlet opening and a separate outlet opening. In such embodiments, coolant fluid may be directed to the separate inlet openings and from the separate outlet openings using a manifold disposed above the openings in the Z-axis direction.

In some embodiments, a height in the Z-axis direction of the coolant channels may be greater than 100 μm, 100 μm-1000 μm, or 100 μm-700 μm. A width in the Y-axis direction of the coolant channels may be greater than 100 μm, 100 μm-1000 μm, or 100 μm-700 μm. For example, the width of the coolant channels may be greater than the height. A cross-section of the coolant channels in the Y-Z plane is wide enough to allow for a pressure drop of 0-20 psi, 3-15 psi, 4-10 psi.

In some embodiments, preparing a desired surface roughness of the sidewalls of the coolant coolant channels may include depositing an organic layer on a photoresist layer after cold plate features have been etched to form a micromasking layer, such as between 1 to 30 nm. The micromasking layer may be dry etched to form the desired surface roughness, such as between 0.1 to 3.0 nm.

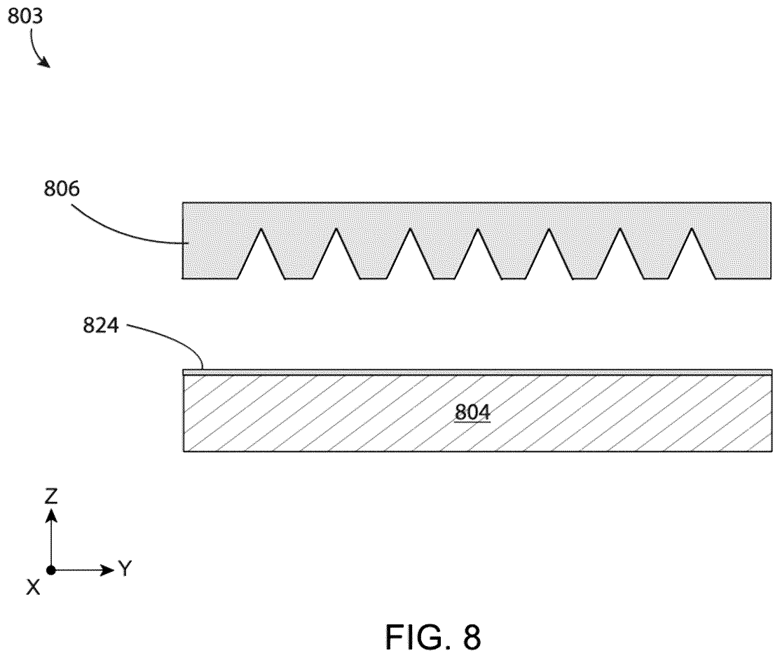

With reference to FIG. 3, the cold plate 206 is attached to the backside 220 of the device 204 without the use of an intervening adhesive, e.g., the cold plate 206 may be directly bonded to the backside 220 of the device 204, such that the cold plate 206 and the backside 220 of the device 204 are in direct contact. For example, in some embodiments, one or both of the cold plate 206 and the backside 220 of the semiconductor device 204 may comprise a dielectric material layer, e.g., a first dielectric material layer 224A and a second dielectric material layer 224B respectively, and the cold plate 206 is directly bonded to the backside 220 of the semiconductor device 204 through bonds formed between the dielectric material layers 224A, 224B. In some embodiments, the second dielectric material layer 224B may be a multifunctional layer, as discussed in more detail below in relation to FIGS. 8 to 10. In some embodiments, one of the cold plate 206 or the backside 220 of the semiconductor device 204 may comprise a thin bonding dielectric layer (e.g. silicon nitride, etc.) and other element(s) may not include any such explicit bonding dielectric layer (or can have only native oxide layer). The first and second dielectric material layers 224A, 224B may be continuous or non-continuous. For example, the first dielectric material layer 224A may be disposed only on lower surfaces of the cold plate 206 facing the backside 220 of the semiconductor device 204. With reference to FIG. 4, described below, portions of the first dielectric material layer 224A may be disposed only on lower surfaces of cavity dividers 230. Beneficially, directly bonding the cold plate 206 to the semiconductor device 204, as described above, reduces the thermal resistance therebetween and increases the efficiency of heat transfer from the semiconductor device 204 to the cold plate 206. In particular, thermal resistance is reduced by directly bonding lower surfaces of the cavity dividers 230 facing the semiconductor device 204 to the backside 220 of the semiconductor device 204.

FIG. 4 is a schematic sectional view in the Y-Z plane of the integrated cooling assembly 203. In FIG. 4, the cold plate 206 comprises a patterned side that faces towards the semiconductor device 204 and an opposite side that faces towards the package cover 208 (not shown). The patterned side comprises plural coolant channels 210 which extend laterally between the inlet and outlet openings of the cold plate 206. Each coolant channel 210 comprises cavity sidewalls which define a corresponding coolant channel 210. The coolant channels 210 extend through the cold plate 806 in the X-axis direction and are spaced apart from each other along the cold plate 806 in the Y-axis.

Portions of the cold plate 206 between the cavity sidewalls form the cavity dividers 230, which function as support features. The cavity dividers 230 provide structural support to the integrated cooling assembly 203 and disrupt laminar fluid flow at the interface of the coolant and the device backside 220, resulting in increased heat transfer therebetween. Furthermore, by introducing plural coolant channels 210 to define separate coolant flow paths, an internal surface area of the cold plate 206 is increased, which further increases the efficiency of heat transfer.

In FIG. 4, arrows 228A and 228B illustrate two different heat transfer paths in the integrated cooling assembly 203. A first heat transfer path illustrated by arrow 228B shows heat generated by the semiconductor device 204 transferring directly from the semiconductor material of the semiconductor device 204 to coolant fluid flowing through the cold plate 206. A second heat transfer path illustrated by arrows 228A shows heat generated by the semiconductor device 204 being transferred from semiconductor material (e.g., silicon material) of the semiconductor device 204 to semiconductor material (e.g., silicon material) of the cold plate 206 structure, propagated throughout the semiconductor material of the cold plate 206 structure (shown as dashed lines), and being transferring into coolant fluid flowing through the cold plate 206. A thermal resistance of the first and second heat transfer paths 228A, 228B is illustrated by heat transfer path 228C, which is shown as thermal resistance R1 between a heat source and a cold plate. Here, R1 is the thermal resistance of the bulk semiconductor material of the semiconductor device 204. It can be seen that the heat transfer path 228C of the integrated cooling assembly 203 is reduced compared to the heat transfer path 26 of the device package 10 of FIG. 1, due to the direct bonding discussed above.

In some embodiments, the cold plate 206 may be attached to the semiconductor device 204 using a hybrid bonding technique, where bonds are formed between the dielectric material layers 224A, 224B and between metal features, such as between first metal pads and second metal pads, disposed in the dielectric material layers 224A, 224B.

Suitable dielectrics that may be used as the dielectric material layers 224A, 224B include silicon oxides, silicon nitrides, silicon oxynitrides, silicon carbon nitrides, metal-oxides, metal-nitrides, silicon carbide, silicon oxycarbides, silicon oxycarbonitride, diamond-like carbon (DLC), or combinations thereof. In some embodiments, one or both of the dielectric material layers 224A, 224B are formed of an inorganic dielectric material, e.g., a dielectric material substantially free of organic polymers. Typically, a dielectric layer may be deposited to a thickness greater than the thickness of a native oxide, such as about 1 nanometer (nm) or more, 5 nm or more, 10 nm or more, 50 nm or more, or 100 nm or more. In some embodiments, a dielectric layer may be deposited to a thickness of 3 μm or less, 1 μm or less, 500 nm or less, such as 100 nm or less, or 50 nm or less. As discussed in more detail below, a thickness of the layers may be optimized for lower thermal resistance between the semiconductor device and the cold plate.

The cold plate 206 may be formed of any suitable material that has sufficient structural strength to withstand the desired pressures of coolant flowing into the coolant channels 210. For example, the cold plate 206 may be formed of semiconductor material like silicon or other engineered materials like glass. In other examples, the cold plate 206 may be formed of a material selected from a group comprising polymers, metals, ceramics, or composites thereof. In some embodiments, the cold plate 206 may be formed of stainless steel (e.g., from a stainless steel metal sheet) or a sapphire plate.

In some embodiments, the cold plate 206 may be formed of a bulk material having a substantially similar coefficient of linear thermal expansion (CTE) to the bulk material of the substrate 202, where the CTE is a fractional change in length of the material (in the X-Y plane) per degree of temperature change. In some embodiments, the CTEs of the cold plate 206 and the substrate 202 are matched so that the CTE of the substrate 202 is within about +/−20% or less of the CTE of the cold plate 206, such as within +/−15% or less, within +/−10% or less, or within about +/−5% or less when measured across a desired temperature range. In some embodiments, the CTEs are matched across a temperature range from about −60° C. to about 100° C. or from about −60° C. to about 175° C. In one example embodiment, the matched CTE materials each include silicon.

In some embodiments, the cold plate 206 may be formed of a material having a substantially different CTE from the semiconductor device 204, e.g., a CTE mismatched material. In such embodiments, the cold plate 206 may be attached to the semiconductor device 204 by a compliant adhesive layer (not shown) or a molding material that absorbs the difference in expansion between the cold plate 206 and the semiconductor device 204 across repeated thermal cycles.

The package cover 208 generally comprises one or more vertical or sloped sidewall portions 208A and a lateral portion 208B that spans and connects the sidewall portions 208A. The sidewall portions 208A may extend upwardly from a peripheral surface of the package substrate 202 to surround the device 204 and the cold plate 206 disposed thereon. The lateral portion 208B may be disposed over the cold plate 206 and is typically spaced apart from the cold plate 206 by a gap corresponding to the thickness of the sealing material layer 222. Coolant is circulated through the coolant channels 210 through the inlet and outlet openings 212 of the package cover 208 formed through the lateral portion 208B. The inlet and outlet openings 206A of the cold plate 206 may be in fluid communication with the inlet and outlet openings 212 of the package cover 208 through the inlet and outlet openings 222A formed in the sealing material layer 222 disposed therebetween. In certain embodiments, coolant lines 108 (FIGS. 2A-2B) may be attached to the device package 201 by use of connector features formed in the package cover 208, such as threads formed in the sidewalls of the inlet and outlet openings 212 of the package cover 208 and/or protruding features 214 that surround the inlet and outlet openings 212 and extend upwardly from a surface of the lateral portion 208B.

Typically, the package cover 208 is formed of semi-rigid or rigid material so that at least a portion of the downward force exerted on the package cover 208 by the mounting frame is transferred to a supporting surface of the package substrate 202 and not transferred to the cold plate 206 and the semiconductor device 204 therebelow. In some embodiments, the package cover 208 is formed of a thermally conductive metal, such as aluminum or copper. In such embodiments, the package cover 208 functions as a heat spreader that redistributes heat from one or more electronic components of the semiconductor device 204.

It should be noted that the direction in which coolant fluid flows through the cold plate 206 may be controlled depending on the relative locations of the inlet and outlet openings. For example, coolant fluid may flow from left to right in the device package 201 of FIG. 3 when the inlet openings 212, 222A, 206A of the package cover 208, the sealing material layer 222, and the cold plate 206, respectively, are located on the left-hand side of the device package 201 and the outlet openings 212, 222A, 206A of the package cover 208, the sealing material layer 222, and the cold plate 206, respectively, are located on the right-hand side of the device package 201. Alternatively, coolant fluid may flow from right to left in the device package 201 illustrated in FIG. 3 when the outlet openings 212, 222A, 206A of the package cover 208, the sealing material layer 222, and the cold plate 206 are located on the left-hand side of the device package 201 and the inlet openings 212, 222A, 206A of the package cover 208, the sealing material layer 222, and the cold plate 206 are located on the right-hand side of the device package 201. Although only one set of inlet and outlet openings are shown and described here, additional inlet and outlet openings may also be provided at various locations on the package cover 208, the sealing material layer 222, and the cold plate 206.

An example flow path of the coolant fluid through the coolant chamber volume may be as follows:
1. Coolant fluid enters the coolant chamber volume through the inlet openings.
2. Coolant fluid flows across the inside surfaces of the cold plate 206 and absorbs heat generated by the semiconductor device 204 which has dissipated into the cold plate 206 structure. The coolant fluid may also flow directly across the backside 220 of the semiconductor device 204 to absorb heat energy directly from the semiconductor device 204. The coolant chamber volume has various coolant channels 210 formed to direct the coolant fluid flow from inlet opening(s) to outlet opening(s) and facilitate heat extraction from the semiconductor device 204 by the coolant fluid. In some embodiments, the coolant fluid may be in direct contact with the backside 220 of the semiconductor device 204 or via one or more substrate or layers between the coolant fluid or backside 220 of the semiconductor device 204.
3. Coolant fluid exits the coolant chamber volume through outlet openings.
   It will be understood from the above flow path that heat is extracted without introducing an unnecessary thermal resistance (such as, for example, a TIM disposed between the backside 220 of the semiconductor device 204 and the cold plate 206) between the backside 220 of the semiconductor device 204 and the cold plate 206.

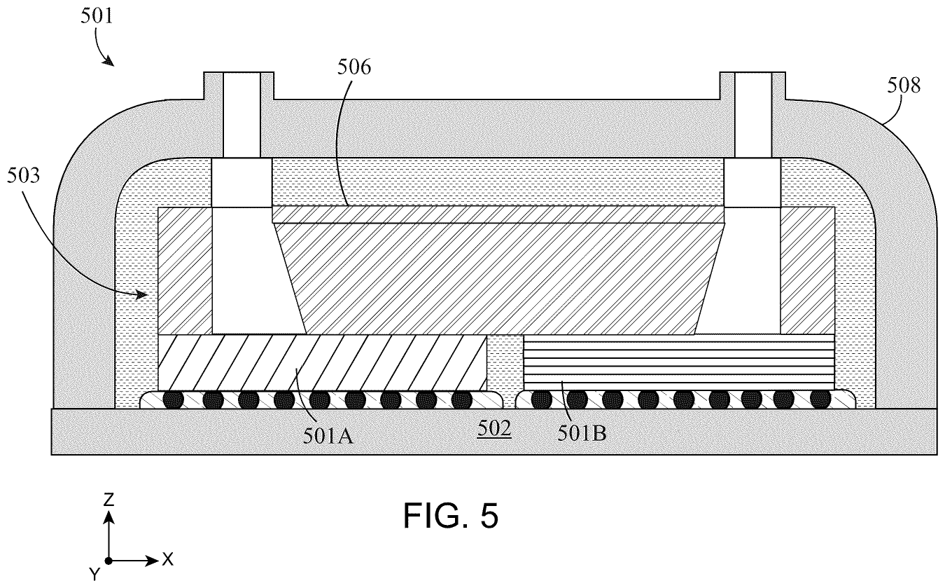

FIG. 5 is a schematic side sectional view in the X-Z plane of an example of a multi-component device package 501 that includes a cold plate 506 directly bonded to the backside surfaces of two or more devices 501A, 501B. The multi-component device package 501 may be similar to the device package 201 described above, and therefore the description of similar features is omitted for brevity. In some embodiments, the two or more devices 501A and 501B are reconstituted and then bonded to the cold plate 506. As shown, the device package 501 includes a package substrate 502, an integrated cooling assembly 503 and a package cover 508. The integrated cooling assembly 503 may include a plurality of devices 501A (one shown) which may be singulated and/or disposed in a vertical device stack 501B (one shown). The cold plate 506 may be attached to each of the devices 501A and device stack 501B, e.g., by the direct bonding methods described herein or other method including flip chip bonding, etc. In some embodiments, the device 501A may comprise a processor and the device stack 501B may comprise a plurality of memory devices. Here, the device 501A and the device stack 501B are disposed in a side-by-side arrangement on the package substrate 502 and are in electrical communication with one another through conductive elements formed in, on, or through the package substrate 502. Here, the cold plate 506 is sized to provide a bonding surface for attachment to both the device 501A and the device stack 501B but may otherwise be the same or substantially similar to other cold plates described herein. In some embodiment, the lateral dimensions (or footprint) of the cold plate 506 may be smaller or larger than the combined lateral dimensions (or footprint) of both the device 501A and the device stack 501B. In some embodiments, one or more sidewalls of the cold plate 506 may be aligned or offset to the vertical sidewalls of the device 501A and the device stack 501B (including inside or outside their footprint). In some embodiment, more than one cold plate 506 may be bonded. For example, separate cold plates may be bonded to the device 501A and the device stack 501B.

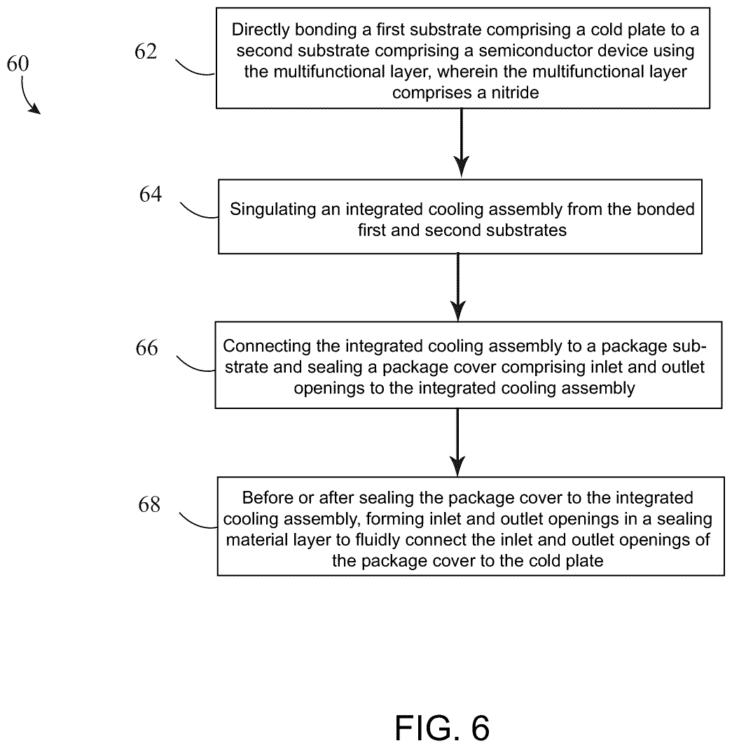

FIG. 6 is a flow diagram setting forth a method 60 of forming an integrated cooling assembly, according to embodiments of the disclosure. Generally, the method includes bonding a first substrate comprising one or more cold plates 206 to a second substrate comprising one or more semiconductor devices 204, and singulating one or more integrated cooling assemblies 203 from the bonded first and second substrates. For example, wafer (bare or reconstituted wafer) comprising one or more cold plates 206 can be directly bonded to another wafer (bare or reconstituted wafer) comprising one or more semiconductor devices 204.

It will be understood that the first substrate may be a cold plate die or part of a wafer of cold plates. Further, the second substrate may be a semiconductor device die or part of a wafer of semiconductor devices 204. Therefore, the method 60 may include die-to-die direct bonding (e.g., cold plate die to semiconductor device die), wafer-to-die direct bonding (e.g., cold plate die to semiconductor device wafer, or cold plate wafer to semiconductor device die), and wafer-to-wafer direct bonding (e.g., cold plate wafer to semiconductor device wafer). It will be understood that the singulation step (discussed in relation to block 64, below) may not be required for a die-to-die direct bonding operation.

For simplicity, the following description is focused on forming one integrated cooling assembly 203 comprising one cold plate 206 and one semiconductor device 204. However, as mentioned above, in some embodiments, the first substrate may comprise plural cold plates 206 and the second substrate may comprise plural semiconductor devices 204, such that plural integrated cooling assemblies 203 may be formed from the first and second substrates.

At block 62, the method 60 includes directly bonding the first substrate (e.g., a monocrystalline silicon wafer) comprising a cold plate 206 to the second substrate (e.g., a monocrystalline silicon wafer) comprising a semiconductor device 204 using a multifunctional layer which comprises a nitride, such as an SiₓO_{y}N_{z}, an insulating nitride, a silicon nitride, an oxynitride, a silicon oxynitride, or a silicon carbon nitride, etc. (e.g., without an intervening adhesive).

In some embodiments, the first substrate may be etched using a patterned mask layer formed on its surface to form features of the cold plate 206. An anisotropic etch process may be used, which uses inherently differing etch rates for the silicon material as between {100} plane surfaces and {111} plane surfaces when exposed to an anisotropic etchant.

In some embodiments, the etching process is controlled to where the etch rates of the substrate surfaces have a ratio between about 1:10 and about 1:200, such as between about 1:10 and about 1:100, for example between about 1:10 and 1:50, or between about 1:25 and 1:75. Examples of suitable anisotropic wet etchants include aqueous solutions of potassium hydroxide (KOH), ethylene diamine and pyrocatechol (EPD), ammonium hydroxide (HN₄OH), hydrazine (N₂H₄), or tetra methyl ammonium hydroxide (TMAH). The actual etch rates of the silicon substrate depend on the concentration of the etchant in the aqueous solution, the temperature of the aqueous solution, and a concentration of the dopant in the substrate (if any). Typically, the mask layer is formed of a material which is selective to anisotropic etch compared to the underlying monocrystalline silicon substrate. Examples of suitable mask materials include silicon oxide (SiₓO_{y}) or silicon nitride (SiₓN_{y}). In some embodiments, the mask layer has a thickness of about 100 nm or less, such as about 50 nm or less, or about 30 nm or less. The mask layer may be patterned using any suitable combination of lithography and material etching patterning methods.

The second substrate may include a bulk material, and a plurality of material layers disposed on the bulk material. The bulk material may include any semiconductor material suitable for manufacturing semiconductor devices, such as silicon, silicon carbide, silicon germanium, germanium, group III-V semiconductor materials, group II-VI semiconductor materials, or combinations thereof. While some high-performance processors like central processing units (CPUs), graphics processing units (GPUs), neural processing units (NPUs), and tensor processing units (TPUs) are typically made out of silicon, some other high power density (hence substantial heat generating) devices may comprise silicon carbide or gallium nitride, for example. In some embodiments, the second substrate may include a monocrystalline wafer, such as a silicon wafer, a plurality of device components formed in or on the silicon wafer, and a plurality of interconnect layers formed over the plurality of device components. In other embodiments, the second substrate may comprise a reconstituted substrate, e.g., a substrate formed from a plurality of singulated devices embedded in a support material. In some embodiments, each semiconductor device may have its own individual cold plate fabricated through a reconstitution process.

The bulk material of the second substrate may be thinned after the semiconductor device 204 is formed using one or more backgrinding, etching, and polishing operations that remove material from the backside. Thinning the second substrate may include using a combination of grinding and etching processes to reduce the thickness (in the Z-direction) to about 450 μm or less, such as about 200 μm or less, or about 150 μm or less or about 50 μm or less. After thinning, the backside 220 may be polished to a desired smoothness using a chemical mechanical polishing (CMP) process, and the dielectric material layer may be deposited thereon. In some embodiments, the dielectric material layer may be polished to a desired smoothness to prepare the second substrate for the bonding process. In some embodiments, the method 60 includes forming a plurality of metal features in the dielectric material layer in preparation for a hybrid bonding process, such as by use of a damascene process.

In some embodiments, the active side of the second substrate is temporarily bonded to a carrier substrate (not shown) before or after the thinning process. When used, the carrier substrate provides support for the thinning operation and/or for the thinned material to facilitate substrate handling during one or more of the subsequent manufacturing operations described herein.

Here, the method 60 may include forming material layers on one or both the first and second substrates, and directly bonding includes forming direct bonds between a multifunctional layer of the first substrate and a dielectric material layer of the second substrate (or forming direct bonds between one substrate and a dielectric material layer or a multifunctional layer of the other substrate). Direct bonding processes join material layers by forming strong chemical bonds (e.g., covalent bonds) between the material layers.

Generally, directly bonding the surfaces (of the layers formed on the first and second substrates) includes preparing, aligning, and contacting the surfaces. Examples of dielectric material layers include silicon oxide, silicon nitride, silicon oxynitride, and silicon carbonitride. Examples of multifunctional layer materials include nitrides, and, in particular, an SiₓO_{y}N_{z}, an insulating nitride, a silicon nitride, an oxynitride, a silicon oxynitride, or a silicon carbon nitride, etc.. Preparing the surfaces may include smoothing the respective surfaces to a desired surface roughness, such as between 0.1 to 3.0 nm RMS, activating the surfaces to weaken or open chemical bonds in the material, and terminating the surfaces with a desired species. Smoothing the surfaces may include polishing the first and second substrates using a CMP process. Activating and terminating the surfaces with a desired species may include exposing the surfaces to radical species formed in a plasma. The bond interface between the bonded layers can include a higher concentration of materials from the activation and/or last chemical treatment processes compared to the bulk of the bonding layers. For example, some embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces.

In some embodiments, the plasma is formed using a nitrogen-containing gas, e.g., N₂, and the terminating species includes nitrogen, or nitrogen and hydrogen. In some embodiments, fluorine may also be present within the plasma. In some embodiments, the surfaces may be activated using a wet cleaning process, e.g., by exposing the surfaces to an aqueous ammonia solution. In some embodiments, the direct bonds may be formed using a multifunctional layer deposited on only one of the first and second substrates, but not on both. In those embodiments, the direct bonds may be formed by contacting the deposited multifunctional layer of one of the first and second substrates directly with a bulk material surface (or such a surface with a native oxide) of the other substrate.

Directly forming direct bonds between the first and second substrates at block 62 may include bringing the prepared and aligned surfaces into direct contact at a temperature less than 150° C., such as less than 100° C., for example, less than 30° C., or about room temperature, e.g., between 20° C. and 30° C. Without intending to be bound by theory, in the case of directly bonding surfaces terminated with nitrogen and hydrogen (e.g., NH₂ groups), it is believed that the hydrogen terminating species diffuse from the interfacial bonding surfaces, and chemical bonds are formed between the remaining nitrogen species during the direct bonding process. In some embodiments, the direct bond is strengthened using an anneal process, where the substrates are heated to and maintained at a temperature of greater than about 30° C. and less than about 450° C., for example, greater than about 50° C. and less than about 250° C., or about 150° C. for a duration of about 5 minutes or more, such as about 15 minutes. Typically, the bonds will strengthen over time even without the application of heat. Thus, in some embodiments, the method does not include heating the substrates.

In embodiments where the first and second substrates are bonded using hybrid dielectric and metal bonds, the method 60 may further include planarizing or recessing the metal features below the field surface before contacting and bonding. After the direct bonds are formed, the first and second substrates may be heated to a temperature of 150° C. or more and maintained at the elevated temperature for a duration of about 1 hour or more, such as between 8 and 24 hours, to form direct metallurgical bonds between the metal features.

Suitable direct dielectric and hybrid bonding technologies that may be used to perform aspects of the methods described herein include ZiBond® and DBI®, each of which are commercially available from Adeia Holding Corp., San Jose, CA, USA.

At block 64, the method 60 includes singulating at least one integrated cooling assembly 203 from the bonded first and second substrates. Singulation after bonding may impart distinctive structural characteristics on the integrated cooling assembly 203 as the bonding surface of the cold plate 206 has the same perimeter as the backside of the semiconductor device 204 bonded thereto. Thus, the sidewalls (e.g., side surfaces) of the cold plate 206 are typically flush with the edges (e.g., side surfaces) of the semiconductor device 204 about their common perimeters. In some embodiments, the cold plate 206 is singulated from the first substrate using a process that cuts or divides the first substrate in a vertical plane, i.e., in the Z-direction. In those embodiments, the side surfaces of the cold plate 206 are substantially perpendicular to the backside 220 of the semiconductor device 204, i.e., a horizontal (X-Y) plane of an attachment interface between the semiconductor device 204 and the cold plate 206. In some embodiments, the cold plate 206 is singulated using a saw or laser dicing process.

At block 66, the method may include connecting the integrated cooling assembly 203 to the package substrate 202 and sealing a package cover 208 comprising inlet and outlet openings 212 to the integrated cooling assembly 203 by use of a molding compound that when cured, forms a sealing material layer 222.

At block 68, the method 60 may include, before or after sealing the package cover 208 to the integrated cooling assembly 203, forming inlet and outlet openings 222A in the sealing material layer 222 to fluidly connect the inlet and outlet openings 212 of the package cover 208 to the cold plate 206.

In some embodiments, the method further comprises thermally oxidising the cold plate 206 before directly bonding the cold plate 206 to the semiconductor device 204.

FIG. 7 shows an isometric view of an example cold plate 706 which may be used as part of the integrated cooling assembly 203 of FIG. 3, according to embodiments of the disclosure. The cold plate 706 shown in FIG. 7 generally corresponds to the cold plate 206 shown in FIG. 2, and therefore description of like features will be omitted for brevity. The cold plate 706 of FIG. 7 includes an inlet opening 706A, an outlet opening 706A, two cavity dividers 730A, 730B, and three coolant channels 710A, 710B, 710C extending laterally between the inlet opening 706A and the outlet opening 706A. As can be seen in FIG. 7, the three coolant channels 710A, 710B, 710C form a generally triangular cross-section and extend along the cold plate 706 between the inlet opening 706A and the outlet opening 706A. The cold plate 706 of FIG. 7 includes three coolant channels, but as described herein, the cold plate 706 may include more than three or less than three coolant channels, for example, as illustrated in FIG. 4. Arrow 712 illustrates a fluid flow path of coolant fluid flowing through the cold plate 706. Here, the fluid flow path illustrates coolant fluid entering the cold plate 706 via the inlet opening 706A, flowing through the three coolant channels 710A, 710B, 710C, and exiting out of the outlet opening 706A.

Embodiments of the disclosure related to using a multifunctional layer to bond a cold plate to a semiconductor device will now be discussed. It will be understood that references to direct bonding, direct dielectric bonding and direct hybrid bonding in the following embodiments refer to the corresponding bonding techniques discussed above. It will also be understood that, in the following embodiments, a semiconductor device may be provided with a multifunctional layer independently of a cold plate. That is, a multifunctional layer may be applied to a backside of a semiconductor device (e.g., a semiconductor device wafer or a semiconductor device die), as discussed below, without the semiconductor device die or wafer subsequently being bonded to a cold plate die or wafer.

Typically, cooling systems may comprises multiple components (e.g., plumbing components) made of various materials through which coolant fluid flows. Elements of these materials may enter the coolant fluid as the coolant fluid flows through the cooling system, which introduces contaminates into the coolant fluid. Example materials which may form contaminants in the coolant fluid include: copper, aluminum, iron, and steel. The coolant fluid itself may also include contaminants, such as glycol, ionised water (e.g., water comprising sodium and/or potassium ions), and corrosion inhibitors (e.g., benzotriazole and/or tolyltriazole).

In general, it is desirable to prevent contaminants from contacting surfaces of a semiconductor device. For example, it is desirable to prevent contaminants which are present in the coolant fluid from diffusing into semiconductor material (e.g., silicon) of a semiconductor device and causing components (e.g., electronic components) of the semiconductor device to malfunction. Where the semiconductor device includes components made from copper or gold materials, metal ions can diffuse through the silicon and form deep level electron traps for the electronic components, which can cause the electronic components to malfunction. The diffusion of metal ions through the semiconductor material increases over a period of time and/or when the semiconductor device is exposed to heat. Therefore, in cooling systems which expose a backside of the semiconductor device to coolant fluid which has previously flowed through a cooling system, it is advantageous to provide a diffusion barrier layer to protect the semiconductor device from contaminants.

Where a cold plate made of silicon is directly bonded (using direct bonding techniques described herein) to a backside of a semiconductor device made of silicon, voids may be present between the directly bonded silicon surfaces. Therefore, it is advantageous to provide at least one dielectric material layer therebetween to reduce voids and improve bonds, as discussed above in relation to the dielectric material layers 224A, 224B of the integrated cooling assembly 203 illustrated in FIG. 3.

In view of the above, it would be beneficial to provide a multifunctional layer between the cold plate and semiconductor device, as illustrated by multifunctional layers 824, 924, 1024, 1024 of FIGS. 8-11, discussed below. Example materials that may be used to form a multifunctional layer include nitrides, such as an SiₓO_{y}N_{z}, an insulating nitride, a silicon nitride, an oxynitride, a silicon oxynitride, or a silicon carbon nitride, etc.. Advantageously, a multifunctional layer functions as a diffusion barrier layer and also functions as a dielectric material layer for direct bonding. A multifunctional layer may alternatively be referred to as a barrier-bonding layer.

FIG. 8 is a schematic sectional view in the Y-Z plane of an example integrated cooling assembly 803, in accordance with embodiments of the disclosure, which may be used as part of the device package 201 of FIG. 3. The integrated cooling assembly 803 comprises a cold plate 806 and a semiconductor device 804. Here, the semiconductor device 804 is bonded to the cold plate 306 using a multifunctional layer 824.

The multifunctional layer 824 may be disposed between the cold plate 806 and a backside of the semiconductor device 804 at a certain thickness. For example, a thickness of the multifunctional layer 824 in a direction orthogonal to a backside of the semiconductor device 804 (i.e., the Z-axis direction) may be less than or equal to 1 μm or less than or equal to 50 nm, for example. In some embodiments, the thickness of the multifunctional layer 824 in the direction orthogonal to the backside of the semiconductor device 804 may be 20 nm to 1 μm or 20 nm to 50 nm, for example. In other embodiments, the thickness of the multifunctional layer 824 in the direction orthogonal to the backside of the semiconductor device 804 may be 20 nm to 40 nm.

By providing a relatively thin single material layer which provides multifunctionality, a thickness of materials disposed between bonded surfaces of the cold plate 806 and the semiconductor device 804 is minimised compared to systems which require individual layers to be stacked in order to provide the same functionality (e.g., a vertical stack of layers comprising a diffusion barrier layer and a dielectric material layer). In other words, only a single multifunctional layer is disposed between the bonded surfaces with no other material layers. Advantageously, by reducing the thickness of materials disposed between bonded surfaces, thermal resistance therebetween is reduced and cooling efficiency is improved.

In embodiments where the semiconductor material of the semiconductor device 804 comprises silicon and the multifunctional layer 824 comprises nitride, the thermal resistance of the silicon nitride interface formed between bonded surfaces of the (silicon) cold plate 806 and the semiconductor device 804 is about 30 Watts/m-K. Therefore, the multifunctional layer 824 provides a relatively high thermal conductivity compared to the thermal conductivity of a silicon-oxide interface formed by an oxide dielectric material layer, which is about 1.2 Watts/m-K. That is, the thermal conductivity of a silicon nitride interface formed with the multifunctional layer 824 may be around 30 times greater than the thermal conductivity of a silicon-oxide interface formed with an oxide dielectric material layer. Hence, the multifunctional layer 824 improves the transfer of heat energy from the semiconductor device 804 to the cold plate 806, which further improves cooling efficiency.

As illustrated in FIG. 8, the multifunctional layer 824 may be disposed on the backside of the semiconductor device 804. The multifunctional layer 824 may be a continuous layer of material that extends across the entire backside of the semiconductor device 804. For example, the multifunctional layer 824 may be deposited on the backside of the semiconductor device using chemical vapor deposition. In such embodiments, the cold plate 806 may be attached to the backside of the semiconductor device 804 using direct dielectric bonds or direct hybrid bonds (as discussed above) formed between the multifunctional layer 824 and the cold plate 806 (e.g., a lower silicon surface of the cold plate 806 facing the backside of the semiconductor device 804).

The plasma activation method discussed above in relation to activating and terminating bonding surfaces may be also be used to activate a surface of the multifunctional layer 824. However, in embodiments where the multifunctional layer 824 comprises nitride, the plasma activation process may use oxygen plasma, rather than nitrogen plasma as discussed above.

In FIG. 8, the cold plate 806 comprises seven coolant channels which extend substantially in parallel through the cold plate 806 in the X-axis direction and are spaced apart from each other along the cold plate 806 in the Y-axis. Between each of the coolant channels is a portion of the cold plate 806 which defines a cavity divider (e.g., support feature). The cavity sidewalls slope such that they meet at a point as can be seen in FIG. 8, and are spaced apart at the interface between the cold plate 806 and the semiconductor device 804 so as to form a triangular cross-section.

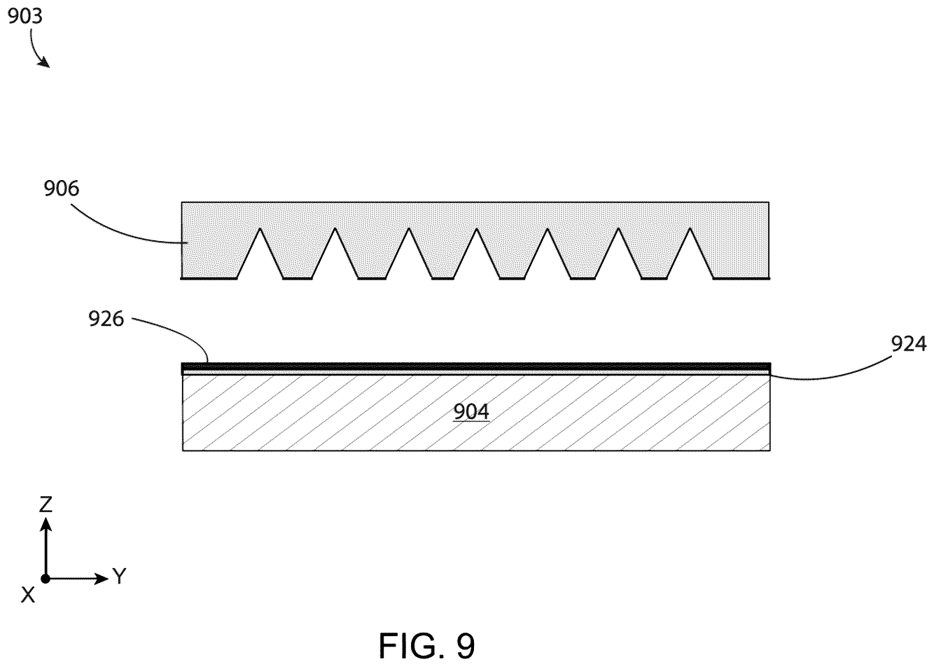

FIG. 9 is a schematic sectional view in the Y-Z plane of an example integrated cooling assembly 903 in accordance with embodiments of the disclosure, which may be used as part of the device package 201 of FIG. 3. The integrated cooling assembly 903 may be similar to the integrated cooling assembly 803 described above, and therefore the description of similar features is omitted for brevity. The integrated cooling assembly 903 comprises a cold plate 906 and a semiconductor device 904. Here, the semiconductor device 904 is bonded to the cold plate 906 using at least a multifunctional layer 924 and a dielectric layer 926. That is, the dielectric layer 926 and the multifunctional layer 924 are disposed between the cold plate 906 and a semiconductor device 904.

In FIG. 9, the dielectric layer 926 is disposed vertically above (e.g., stacked in the Z-axis direction) the multifunctional layer 924, such that the dielectric layer 926 is disposed between the multifunctional layer 924 and the cold plate 906.

In embodiments illustrated by FIG. 9, the multifunctional layer 924 is disposed on the backside of the semiconductor device 904 and the dielectric layer 926 is disposed on the multifunctional layer 924. That is, the multifunctional layer 924 may be a continuous layer of material that extends across the entire backside of the semiconductor device 904 and the dielectric layer 926 may be a continuous layer of material that extends across an entire upper surface of the multifunctional layer 924. For example, the multifunctional layer 924 may be deposited on the backside of the semiconductor device 904 using chemical vapor deposition and the dielectric layer 926 may be deposited on the multifunctional layer 924semicondj using chemical vapor deposition.

In FIG. 9, the cold plate 906 may be attached to the backside of the semiconductor device 904 using direct dielectric bonds or direct hybrid bonds (as discussed above) formed between the dielectric layer 926 and the cold plate 906 (e.g., a lower (silicon) surface of the cold plate 806 facing the backside of the semiconductor device 904).

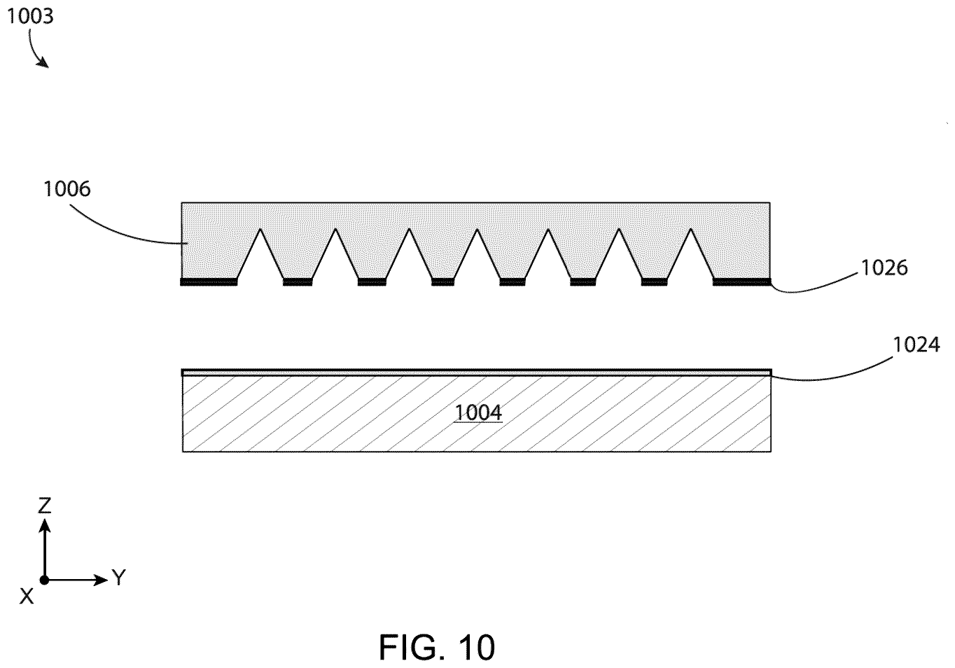

FIG. 10 is a schematic sectional view in the Y-Z plane of an example integrated cooling assembly 1003 in accordance with embodiments of the disclosure, which may be used as part of the device package 201 of FIG. 3. The integrated cooling assembly 1003 may be similar to the integrated cooling assemblies 803, 903 described above, and therefore the description of similar features is omitted for brevity. The integrated cooling assembly 1003 comprises a cold plate 1006 and a semiconductor device 1004. Here, the semiconductor device 1004 is bonded to the cold plate 1006 using at least a multifunctional layer 1024 and a dielectric layer 1026. That is, the dielectric layer 1026 and the multifunctional layer 1024 are disposed between the cold plate 1006 and a semiconductor device 1004.

In FIG. 10, the dielectric layer 1026 is disposed vertically above (e.g., in the Z-axis direction) the multifunctional layer 924, such that the dielectric layer 1026 is disposed between the multifunctional layer 1024 and the cold plate 1006. The integrated cooling assembly of 1003 of FIG. 10 differs from the integrated cooling assembly 903 of FIG. 9 in that the dielectric layer 1026 is disposed on a lower surface of the cold plate 1006, rather than being disposed directly on the multifunctional layer 1024. That is, the multifunctional layer 1024 is disposed on the backside of the semiconductor device 1004 and the dielectric layer 1026 is disposed on the lower surface of the cold plate 1006 opposite (e.g., facing) the backside of the semiconductor device 1004. The multifunctional layer 1024 may be a continuous layer of material that extends across the entire backside of the semiconductor device 1004. The dielectric layer 1026 may be a continuous layer of material disposed on (all) lower surfaces of the cold plate 1006 which face the backside of the semiconductor device 1004. Alternatively, the dielectric layer 1026 may be a non-continuous layer of material disposed (only) on portions of the lower surface of the cold plate 906 (e.g., lower surfaces of the sidewall and the cavity dividers). For example, the multifunctional layer 924 may be deposited on the backside of the semiconductor device 904 using chemical vapor deposition and the dielectric layer 926 may be deposited on the lower surface of the cold plate 906 using chemical vapor deposition.

In FIG. 10, the cold plate 1006 may be attached to the backside of the semiconductor device 1004 using direct dielectric bonds or direct hybrid bonds (as discussed above) formed between the dielectric layer 1026 and the multifunctional layer 1024.

In embodiments comprising a dielectric layer, the dielectric layer may comprise an oxide and/or a nitride, as discussed above in relation to the dielectric material layers 224A, 224B. In embodiments where the dielectric layer comprises an oxide, the oxide may be referred to as a thermal oxide. Furthermore, the dielectric layer may be disposed between a cold plate and a multifunctional layer at a certain thickness. For example, a thickness of the dielectric layer in a direction orthogonal to a backside of the semiconductor device (i.e., the Z-axis direction) may be greater than 50 nm. In some embodiments, the thickness of the dielectric layer in the direction orthogonal to the backside of the semiconductor device may be 50 nm to 1 μm or 50 nm to 100 nm, for example.

Compared to bonding techniques in which two dielectric material layers are used to form direct bonds, embodiments of the present disclosure in which a dielectric layer and a multifunctional layer provide similar advantages to those discussed above in relation to reduced thermal resistance between bonding surfaces and improved thermal transfer.

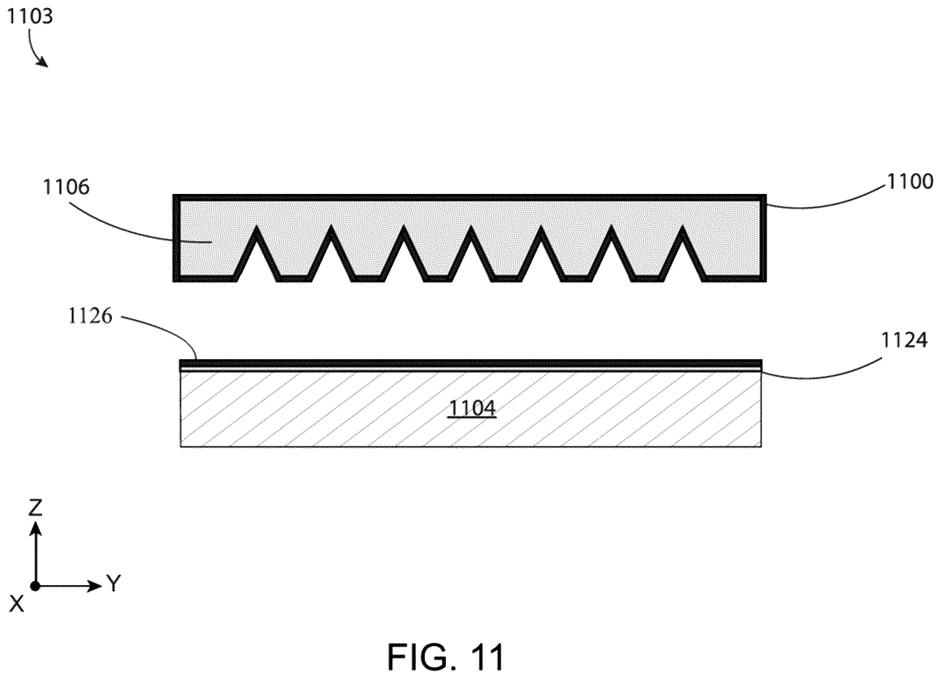

FIG. 11 a schematic sectional view in the Y-Z plane of an example integrated cooling assembly 1103, in accordance with embodiments of the disclosure, which may be used as part of the device package 201 of FIG. 3. The integrated cooling assembly 1103 may be similar to the integrated cooling assemblies 803, 903, 1003 described above, and therefore the description of similar features is omitted for brevity. The integrated cooling assembly 1103 comprises a cold plate 1106 and a semiconductor device 1104. A multifunctional layer 1124 and a dielectric layer 1126 are disposed between the semiconductor device 1104 and the cold plate 1106 in arrangements similar to those discussed above in relation to FIG. 9 and FIG. 10. The cold plate 1106 in FIG. 11 comprises a thermal oxide layer 1100 on (all) external surfaces of the cold plate 1106 (in addition to or instead of the dielectric layer 1126). The thermal oxide layer 1106 may be deposited on surfaces of the cold plate 1106 using patterning techniques or deposition techniques. Advantageously, the thermal oxide layer of the cold plate 1106 improves the structural integrity of the integrated cooling assembly 1103.

The embodiments discussed above are intended to be illustrative and not limiting. One skilled in the art would appreciate that individual aspects of the cooling assemblies, device packages, and methods discussed herein may be omitted, modified, combined, and/or rearranged without departing from the scope of the disclosure.

1. An integrated cooling assembly comprising:
a semiconductor device and a cold plate attached to the semiconductor device by direct bonds with a multifunctional layer disposed therebetween, the cold plate comprising:
a perimeter sidewall;
a top portion; and
a cavity divider comprising cavity sidewalls, wherein:
the perimeter sidewall extends downwardly from the top portion to a backside of the semiconductor device to define a perimeter of the cold plate;
the cavity divider extends downwardly from the top portion towards the backside of the semiconductor device;
the cavity sidewalls, the perimeter sidewall and the backside of the semiconductor device collectively define coolant channels therebetween; and
the multifunctional layer comprises a nitride.

2. The integrated cooling assembly of claim 1, wherein a thickness of the multifunctional layer in a direction orthogonal to the backside of the semiconductor device is less than or equal to 1 μm.

3. The integrated cooling assembly of claim 1, wherein a thickness of the multifunctional layer in a direction orthogonal to the backside of the semiconductor device is less than or equal to 50 nm.

4. The integrated cooling assembly of claim 1, wherein a thickness of the multifunctional layer in a direction orthogonal to the backside of the semiconductor device is 20 nm to 1 μm.

5. The integrated cooling assembly of claim 1, wherein a thickness of the multifunctional layer in a direction orthogonal to the backside of the semiconductor device is 20 nm to 50 nm.

6. The integrated cooling assembly of claim 1, wherein a thickness of the multifunctional layer in a direction orthogonal to the backside of the semiconductor device is 20 nm to 40 nm.

7. (canceled)

8. The integrated cooling assembly of claim 1, wherein the cold plate is attached to the semiconductor device using direct dielectric bonds formed between the multifunctional layer and the cold plate.

9. The integrated cooling assembly of claim 1, wherein the cold plate is attached to the semiconductor device using direct hybrid bonds formed between the multifunctional layer and the cold plate.

10. The integrated cooling assembly of claim 1, further comprising a dielectric layer disposed between the multifunctional layer and the cold plate.

11. (canceled)

12. The integrated cooling assembly of claim 10, wherein the dielectric layer comprises an oxide or a nitride.

13. (canceled)

14. The integrated cooling assembly of claim 10, wherein a thickness of the dielectric layer in a direction orthogonal to the backside of the semiconductor device is 50 nm to 1 μm.

15. The integrated cooling assembly of claim 10, wherein a thickness of the dielectric layer in a direction orthogonal to the backside of the semiconductor device is 50 nm to 100 nm.

16. The integrated cooling assembly of claim 1, wherein the multifunctional layer is disposed on the backside of the semiconductor device and the dielectric layer is disposed on a lower surface of the cold plate opposite the backside of the semiconductor device.

17. The integrated cooling assembly of claim 16, wherein the cold plate is attached to the semiconductor device using direct dielectric bonds formed between the multifunctional layer and the dielectric layer.

18. The integrated cooling assembly of claim 16, wherein the cold plate is attached to the semiconductor device using direct hybrid bonds formed between the multifunctional layer and the dielectric layer.

19. The integrated cooling assembly of claim 10, wherein the multifunctional layer is disposed on the backside of the semiconductor device and the dielectric layer is disposed on the multifunctional layer.

20. The integrated cooling assembly of claim 19, wherein the cold plate is attached to the semiconductor device using direct dielectric bonds formed between the dielectric layer and the cold plate.

21. The integrated cooling assembly of claim 19, wherein the cold plate is attached to the semiconductor device using direct hybrid bonds formed between the dielectric layer and the cold plate.

22. (canceled)

23. The integrated cooling assembly of claim 1, wherein the multifunctional layer comprises an SiₓO_{y}N_{z} nitride.

24-26. (canceled)

27. The integrated cooling assembly of claim 1, wherein:
the cold plate comprises adjacent first and second cavity dividers each comprising cavity sidewalls extending substantially in parallel;
the cavity sidewalls are sloped and form an acute angle with the backside of the semiconductor device; and
opposing cavity sidewalls of the adjacent first and second cavity dividers and the backside of the semiconductor device define a triangular cross-section of a corresponding coolant channel to define plural coolant channels.

28-67. (canceled)
